(19) United States
(12) Patent Application Publication
(10) Pub. No.: US 2009/0173929 A1
(43) Pub. Date: Jul. 9, 2009

(54) DATA MEMORY, WRITABLE AND READABLE BY MICROTIPS, WHICH HAS A WELL STRUCTURE, AND MANUFACTURING METHOD

(75) Inventor: Serge Gidon, La Murette (FR)

Correspondence Address: LOWE HAUPTMAN & BERNER, LLP, 1700 DIAGONAL ROAD, SUITE 300, ALEXANDRIA, VA, 22314, US

(73) Assignee: COMMISSARIAT A L'ENERGIE ATOMIQUE, Paris (FR)

(21) Appl. No.: 12/300,255

(22) PCT Filed: May 29, 2007
(86) PCT No.: PCT/EP07/55163

§ 371 Date: Jan. 14, 2009

(30) Foreign Application Priority Data
May 30, 2006 (FR) 0604809

(51) Int. Cl. H01L 47/00

(52) U.S. Cl. 257/3; 438/780; 365/163; 257/E47.001; 257/E47.005

(57) ABSTRACT

The invention relates to data storage memories, that can be written and read by using at least one write or read microtip which comes near to a point zone to be written or to be read on the surface of a substrate, either in order to change the physical state of this zone, when writing or erasing, or in order to determine the physical state of the zone, when reading, the data stored in the zone being defined by the physical state of the zone. The surface of the substrate is subdivided into a set of individual islands (75) of a layer of a first sensitive material capable of changing state under the action of the write microtip, each island (75) being surrounded by a well (80) formed by a second material which is not or not very sensitive to the action of the write microtip, this second material completely separating the individual islands from one another. The material of the wells is the same as that of the islands, but differentiation impurities distinguish them from one another. The organization into islands and into wells may be obtained by photolithography or by a step of self-organization of materials capable of agglomerating spontaneously into islands.

### CROSS-REFERENCE TO RELATED APPLICATIONS

The present Application is based on International Application No. PCT/EP2007/055163, filed on May 29, 2007, which in turn corresponds to French Application No. 0604809, filed on May 30, 2006, and priority is hereby claimed under 35 USC §119 based on these applications. Each of these applications are hereby incorporated by reference in their entirety into the present application.

### FIELD OF THE INVENTION

The invention relates to data memories that can be written or read by microtips.

### BACKGROUND OF THE INVENTION

In the search for increasingly higher information storage densities, mass storage memories known as microtip mass storage memories have been conceived in which data is written and stored data is read by applying a microtip with an extremely small apex size (few nanometers) against the surface or in the vicinity of the surface of a substrate which bears a sensitive layer that will also be referred to as media.

The application of a write microtip to the sensitive layer makes it possible to locally change the physical state of the layer without modifying the state of the layer around the zone in question. The change of state may be an electrical change of state such as a modification in the resistivity value, or a greater physical change of state (for example to change from an amorphous state to a crystalline state) which, furthermore, most often also induces a modification of electrical, thermal or even chemical properties.

Conversely, the application of a read microtip to a sensitive layer that comprises zones that may or may not have undergone this change of state, that can be referred to as written zones and unwritten zones, makes it possible to read the state of the zone.

The principle of use of a microtip for data storage is inspired notably by studies carried out in the field of atomic force microscopy (AFM); these studies have shown that it is possible to explore a surface using a microtip with an extremely high geometric resolution (nanometer scale).

For an atomic force microscope, the microtip is moved over the surface of an object to explore its relief by measuring the displacements of the microtip; for a data memory, the microtip is moved over the surface of the substrate in order to write data, with a very high density, and to reread them. The density is linked to the dimensions of the microtip and to the position-determining precision of the microtip during its displacement, and also to the actual resolution of the media which depends on the size of the grains of the sensitive layer. In order to increase the data rate when reading or when writing, it has already been proposed to use a multiplicity of microtips in parallel.

The article “The “Millipede”—More than one thousand tips for future AFM data storage”, by P. Vettiger et al., published in IBM Journal of Research and Development, Vol. 44, No. 3 in May 2000, sets out these principles with respect to a data memory in which data is stored by an effect known as a “thermomechanical” technique: the microtip locally heats the sensitive layer zone (a polymer) into which it is pressed; this heating begins by softening the layer; the pressure exerted on the tip forces it into the layer; a hole is created in the layer. For reading, a thermal effect is also used: the electrical resistance exhibited by the tip is heat-sensitive, and the temperature that the tip takes up depends on whether the tip is or is not located in a hole created during the writing process and increases the heat transfer; it is therefore possible, by placing the tip in an electrical measurement circuit, to detect the presence of holes, in relation to the position of the tip.

More generally, these methods inspired by atomic force microscopy have given rise to various experiments using sensitive layer principles which may be different from the principle set out in the previous paragraph.

In European Patent Application EP 0 739 004 A1, the sensitive layer is an insulating layer into which the microtip applies an electric breakdown voltage locally creating an electrically conductive zone in the middle of the insulating environment. Re-reading is electric, by measurement of the current which passes through the microtip. It should be noted that this solution does not allow erasure since the breakdown is irreversible, and the memory is therefore not rewritable, which is a drawback.

The phase change materials, typically from the chalcogenide family such as Ge₂Sb₂Te₅ or AgInSbTe, have also been tried: by thermal action of the microtip on a localized zone, it is possible to change the material locally from an amorphous state to a crystalline state. The state is reversible and it is theoretically possible to erase a written zone by again putting it in the amorphous state, still using heating but under different conditions (in general with a quench, that is to say a rapid cooling).

The article “Electrical probe storage using Joule heating in phase change media”, by S. Gidon et al., published in Applied Physics Letters, Vol. 85, No. 26 on 27 Dec. 2004, describes the principles of such a memory, with the distinctive feature that the heating for the crystallization or for the return to the amorphous state is carried out by Joule effect, by application of a current through the media, starting from the write microtip. The layer is initially amorphous and not very conductive; the writing is carried out by local crystallization, under the effect of a direct Joule heating in the zone in question of the layer. The crystallized material is more conductive than the amorphous material. The reading is carried out by application of a voltage (lower than that used for writing) to a read microtip and measurement of the current that flows, which depends on whether the material has remained amorphous or has been crystallized.

In the article “Ultra-high-density phase-change storage and memory”, by Hendrick F. Hamann et al., published on the site www.nature.com on 9 Apr. 2006, the heating is indirect, the laser-heated microtip transfers its heat to the zone of sensitive layer with which it is in contact; furthermore, reading is carried out by thermal detection: the tip is heated (less than for writing) and the thermal impedance of the tip is measured.

In all these embodiments, assuming that erasure is theoretically possible, it is realized that it is probably very difficult to carry it out practically. The local control of the binary state of a point zone touched by a microtip may be doubtful since the thermal action on a zone has effects on the immediate surroundings of this zone; in particular, it is understood that the heat generated cannot remain completely localized at the location where it is desired. For example, the fact of changing back a crystalline zone into the amorphous state (erasing) may leave or create an undesirable crystalline ring around the zone that has become amorphous again. The residual conductivity of this peripheral ring risks preventing the amorphous nature of the zone that it was desired to erase from being detected.

### SUMMARY OF THE INVENTION

One objective of the invention is notably to facilitate the recording, reading, and erasure of data memory that can be written and read by microtips.

In order to do this, the invention provides a data storage memory, that can be written and read by using at least one write or read microtip which comes near to (in contact with or in the immediate vicinity of) a point zone to be written or to be read on the surface of a substrate, either in order to change the physical state of this zone, when writing or erasing, or in order to determine the physical state of the zone, the data stored in the zone being defined by the physical state of the zone, when reading, characterized in that the surface of the substrate is subdivided into a set of individual islands of a layer of a first sensitive material capable of changing state under the action of the write microtip, each island being surrounded by a well formed by a second material which is not or not very sensitive to the action of the write microtip, this second material completely separating the individual islands from one another.

Thus, instead of using a uniform and continuous sensitive layer for writing data thereto, use is made of a layer previously structured by a network of wells (that is to say, a lattice network of walls) connected to one another, which separates the individual islands from one another; an individual island delimited by the internal periphery of a well constitutes an individual zone corresponding to at least one data item stored.

The sensitive layer is preferably composed of a material capable of changing crystalline phase by controlled thermal action, notably a chalcogenide, and notably a GeSbTe compound of germanium, antimony and tellurium or an AgInSbTe compound of silver, indium, antimony and tellurium, capable of changing from an amorphous state to a crystalline state in a reversible manner under the effect of controlled heating. For the AgInSbTe material, the crystallization properties depend, notably, on the proportion of silver, since silver lowers the crystallization temperature and therefore facilitates the crystallization. Other materials can be envisaged, such as compounds based on germanium and tellurium GeTe or germanium and selenium GeSe. The invention can however be applied to other types of materials, for example polymers capable of changing state and of electrical conduction during a temperature cycle including, for example, a thermal quench (very rapid cooling).

The material of the wells that surround the sensitive layer is preferably an electrically insulating material; preferably, it has a low thermal conductivity. This may notably be a compound of zinc sulfide ZnS and of silica SiO₂, fairly rich in ZnS (70 to 80% by weight for example).

Particularly advantageously from the point of view of the cost and of the manufacturing precision, provision is made for the second material (that of the wells), less sensitive to phase changes than the first material (that of islands), to be formed mainly from the same material as the first, but for the differentiation impurities to be contained in one and/or the other of the two materials. The impurities are chosen so that they facilitate the amorphous/crystalline change of state for the first material (that of the individual islands), and/or so that they make the change of state more difficult for the second material (that of the network of wells which surrounds the islands). The impurity implanted in the islands will preferably be composed of silver, which tends to lower the crystallization temperature and therefore facilitate the crystallization of the material. Conversely, the impurity implanted in the wells should instead increase the crystallization temperature; the impurity could be hafnium or more generally an atom of high atomic number to better aim to hinder any crystallization process. It may also be advantageous, for the impurities implanted in the wells, that these impurities be impurities that tend to reduce the electrical conduction (oxygen, nitrogen, hydrogen, argon, gallium); specifically, the reduction in the conductivity will make a phase change (notably a crystallization phase change) more difficult in the wells whereas this phase change will remain possible in the islands which will not have received this impurity.

In a first exemplary embodiment, the substrate is covered with a layer forming a thermal barrier made from a material that is a poor heat conductor, and with a continuous electrode which covers the barrier layer; the continuous electrode is covered with islands of the layer of sensitive material surrounded by wells formed by the second material; the set of islands and wells is covered with a layer for reducing friction of the microtip; this layer acts as a protective layer against the wear of the microtips and of the media.

The substrate may be made of silicon, glass, or organic material. The layer that forms a barrier may be made of silica, silicon nitride, or preferably from a zinc sulfide ZnS and a silica SiO₂ compound, the latter compound having a low thermal conduction (around 200 times less than silicon). The thickness of the barrier layer may be around 10 nanometers to 100 nanometers.

The electrode may be made of titanium nitride or of carbon; it is preferably made from a material that has both an electrical resistivity intermediate between the resistivities of the two crystalline and amorphous states of the media and a low thermal conductivity. If the electrode is made of carbon, it is possible to add thereto metallic elements such as silver, chromium, nickel, or gold, to adjust the electrical conductivity. The thickness of the electrode may be around 2 to 10 nanometers, for example.

The layer for protection against wear of the microtips may be made of carbon.

In a second exemplary embodiment, the substrate is covered with a layer forming a thermal barrier made from a material that is a poor heat conductor, covered with islands of the sensitive layer; the islands are surrounded by wells formed by the superposition of the second layer, with an electrode and with a third electrically-insulating and thermally-insulating layer; the set of islands and wells is covered with a layer for reducing friction of the microtip; this layer acts as a layer for protection against wear of the microtips and of the media. In this second exemplary embodiment, the electrode (electrically continuous due to the continuity of the wells which are connected to one another) is in a way pierced with an aperture at the location of each island, and the electrical connection between one island and the electrode is achieved by the slice of the electrode around the periphery of the island.

In order to define the geometry that is structured as islands and as wells, it is possible to use etch masks obtained by photolithography, but it is also possible to use processes known as “self-organization” processes: in these processes, a layer of material is deposited under conditions such that the material agglomerates automatically into small islands separated from one another. This self-organization may produce, in very thin layers, a network of islands with a resolution greater than that which photolithography allows. The material thus deposited may act directly as an active material in the final product, or else it may constitute a mask for defining a pattern in another layer, this other layer may optionally itself either constitute a layer of the media, or act itself as a mask for defining a pattern in a third layer.

Consequently, the invention provides a novel process for manufacturing a memory that can be written and read by using at least one write or read microtip which comes near to an elementary zone to be written or to be read on the surface of a substrate, characterized in that the elementary zones are individual islands of a first material, surrounded by wells of a different material, and in that the islands are defined by using a step of self-organization of at least one substance which, during its deposition onto a surface of a substrate, is capable of self-organizing itself into a pattern of individual islands separated from one another.

The substance that self-organizes itself may be an impurity intended to be diffused into a subjacent layer in order to define the individual islands. It may also be a substance that acts as a mask for the treatment of a subjacent layer.

The substance that self-organizes itself may notably be a polymer, this polymer being deposited at the same time as a second polymer that has affinities with the first, the bonding forces between the two polymers creating a self-organization in which the first polymer agglomerates into individual islands surrounded by a matrix of the second polymer.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 represents the principle of a microtip memory;

FIG. 2 represents writing and erasing in the memory from FIG. 1;

FIG. 3 represents the principle of a microtip memory, structured according to the invention;

FIGS. 4 to 9 represent the steps of a process for manufacturing a memory according to the invention in a first exemplary embodiment; and

FIGS. 10 to 15 represent the steps of manufacturing a memory in another exemplary embodiment.

### DESCRIPTION OF PREFERRED EMBODIMENTS

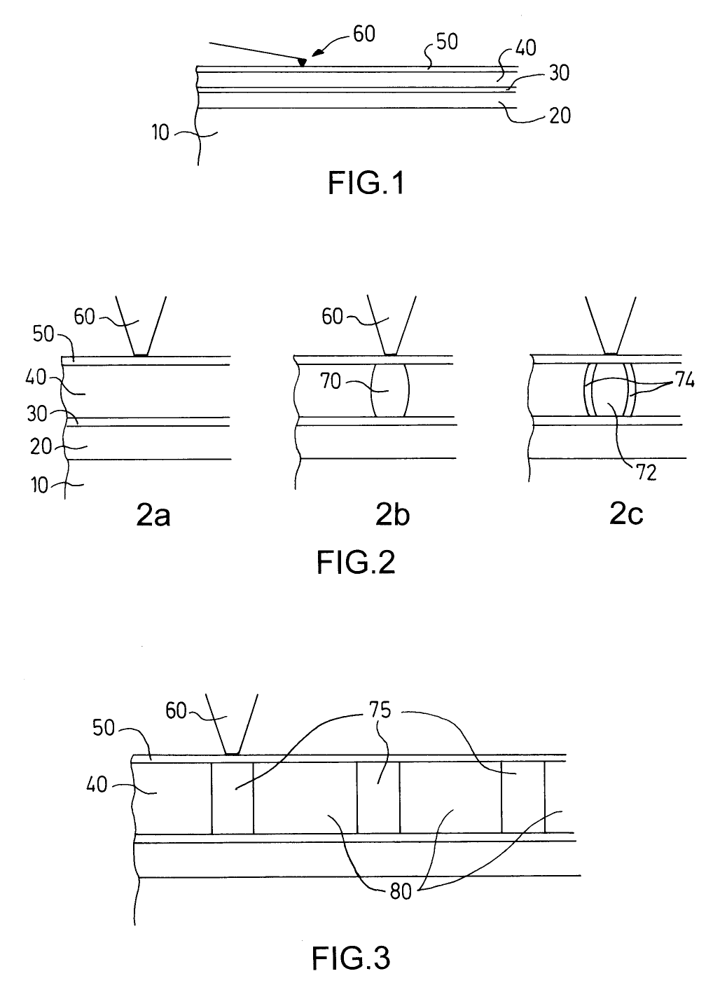

In FIG. 1, the principle of a rewritable microtip memory constituted using a material having controllable phase change is recalled. The expression “phase change” is understood to mean, above all, the change from an amorphous phase to a crystalline phase. It could be possible, if need be, to envisage materials which can change from a first crystalline state to a second crystalline state that can be distinguished from the first. The expression “material having a controllable phase change” is understood to mean a material for which the crystallization temperatures are sufficiently low and the conditions for crystallization or for return to the amorphous state are sufficiently well-known so that it is possible, selectively and voluntarily, under the effect of an electrical control by a microtip, to produce the change from one state to the other. In particular, the transition rates between phases will be less than 10 microseconds.

A substrate 10 is covered with a continuous layer 20 that forms a thermal barrier preventing excessive heat dissipation to the substrate during writing or erasing (too large a heat dissipation will tend to prevent a concentration of heat and therefore a control of the crystallization).

The barrier layer 20 is covered with a continuous electrode 30 which may be brought to a desired potential (a mass potential for example, to simplify the understanding).

The continuous electrode 30 is covered with a continuous layer 40 of a material such as a chalcogenide, notably Ge₂Sb₂Te₅. This material has the property of being able to change phase reversibly, between an amorphous phase and a crystalline phase, by thermal action at temperatures that are relatively easy to attain and under conditions that are known as regards the heating and cooling rates necessary for these phase changes. The layer 40 is the sensitive layer of the memory, it is this which stores the information; the binary information corresponding to a small zone of the layer is the amorphous or crystalline state of this zone.

Finally, the sensitive layer 40 is preferably covered with a layer 50 known as a tribological layer. This layer is used to facilitate the sliding of the read or write microtip over the surface of the substrate for access to the various individual zones of the sensitive layer. It is therefore a layer for protecting against wear of the microtip.

Writing may be carried out, for example, by application of an electrical voltage pulse between the microtip and the electrode (direct Joule heating). Erasing is carried out by application of a voltage pulse of different characteristics (shorter). Reading is carried out by application of a lower voltage to the microtip and measurement of the current which passes through the tip.

Represented in FIG. 1 is a single write or read tip 60, but a multiplicity of tips in a network, individually controlled, may be used to simultaneously access a large number of individual zones and therefore to increase the rapidity of writing or reading the media. The write or read tips are extremely fine tips (of the order of a few nanometers of surface area at their extremity) borne by the end of a cantilevered lever arm.

FIG. 2 schematically represents what happens during the erasing of a memory zone, showing the risk of a poor erasure. It is assumed that the initial erased state of the memory is a state in which the entire sensitive layer is in an amorphous state (FIG. 2a). In this amorphous state, the vertical conductivity of the sensitive layer from the microtip to the electrode 30 is low. Information is created by rendering an individual zone 70 (FIG. 2b) located under the microtip crystalline; this is done by applying direct or indirect heating via the microtip 60, at a temperature that permits crystallization. Heating at around 200° C. for around a hundred nanoseconds makes it possible to do this; this heating may be generated directly (Joule effect) by the flow of a current between the microtip 60 and the electrode 30. In the crystalline state, the electrical conductivity (vertically) is higher between the microtip and the electrode 30. Erasing may be carried out by application of higher heating, of around 600° C. to 700° C. and quenching, that is to say very rapid cooling (of the order of 10 nanoseconds). This remelting followed by a quench makes it possible to reconstitute an amorphous zone instead of the crystalline zone 70. Unfortunately, this amorphous zone is not perfect and in practice it risks being instead in the form of a central amorphous portion 72 surrounded by a peripheral zone 74 which is partly crystalline (FIG. 2c). This results from temperature conditions and cooling rates which are different in the central zone and at the periphery. If this is the case, the memory point is poorly erased since the residual conductivity of the peripheral zone may make one believe, during reading, in the presence of a crystalline zone and not an amorphous zone.

FIG. 3 represents a schematic example of memory structured according to the invention. The memory comprises individual sensitive zones 75 of a controllable phase-change material (compound based on tellurium Te or antimony Sb or germanium Ge, such as GeTe or GeSb or SbTe or a chalcogenide such as GeSbTe, for example Ge₂Sb₂Te₅, or else AgInSbTe) in the form of individual islands surrounded by wells 80 of a material different from the material of the zones 75 (preferably a compound of silica and of zinc sulfide, or optionally of poorly conducting carbon such as hydrogenated carbon). The material of the wells 80 is of a type such that it is less easy to crystallize than the material of the islands 75. The wells form a continuous lattice network, or a sort of regular grid, and the sensitive zones 75 appear as isolated islands in the apertures of this network.

In the example from FIG. 3, the wells, like the sensitive zones, are formed on top of a continuous electrode 30 (for example made of titanium nitride or of carbon rendered conductive by metal adjuvants such as Ag, Cr, Ni, Au, etc.). The electrode 30 is itself formed on top of a layer 20 (preferably a compound of silica and of zinc sulfide) but forms a thermal barrier between the electrode 30 and the substrate 10 (substrate made of silicon or glass or organic material). A tribological protective layer 50 (preferably powdered carbon) is preferably formed on top of the sensitive zones 75 and the wells 80. At the location of the sensitive zones 75, the superposition of layers may therefore be similar to that of FIG. 1.

The material of the wells is chosen from a type that is not or not very sensitive to the action of a current applied by the microtip: it does not change crystalline state as easily as the material of the islands; it is also not very sensitive to the heat generated in the sensitive islands 75 when they are being written or erased; in other words, this material does not easily change state from the point of view of its electrical conductivity, whether this is under the direct action of the write microtip or under the indirect action of the writing of a neighboring island. The material of the wells is therefore advantageously an electrically insulating material (that is to say more insulating than the material of the sensitive zones both when the latter is in a crystalline state and when it is in an amorphous state) so that the currents applied between the microtip 60 and the electrode 30 flow into the sensitive zone on top of which the tip is placed without being diverted into the material of the wells. The material of the wells is preferably a poor heat conductor to aid the localization of the heat in the islands.

Reading is carried out by application, between the microtip (placed on the media on top of an island 75) and the electrode 30, of a sufficient voltage (of around 3 to 5 volts), in view of the high resistivity of the zone of the sensitive layer in the amorphous state, in order to heat the island and bring it to the crystallization temperature during the time necessary for this crystallization. The heating current remains localized in the island and enables the crystallization of the layer, preferably over the entire height of the island. Writing is typically carried out by voltage pulses having a duration of around 100 to 1000 nanoseconds.

Erasing is carried out by application of a high voltage to a crystalline island through the microtip, in order to make the material of the island melt. The voltage pulse which produces the direct heating current necessary for this remelting is very brief and the falling edge of the pulse is particularly brief (less than 10 nanoseconds) in order to induce a very brief cooling time; this produces a sort of quenching, enabling the material to remain in the amorphous state after melting. The small size of the island and the fact that the heating current is very much concentrated in the island means that the whole of the zone becomes amorphous, without risk of peripheral crystalline traces around the zone that has again become amorphous. The fact that the material of the well is relatively thermally insulating facilitates this quality of erasing, and from this point of view the choice of the compound ZnS/SiO₂ for the wells is favorable. The erased pulses may typically last 40 nanoseconds.

It should be noted that the surface layer 50 must have both a sufficient conductivity in the vertical direction so that the current applied by the microtip definitely passes in the vertical direction toward the island 75 and a sufficiently low conductivity in the horizontal direction so that the current is not conducted toward the other islands (among which there may be islands that have changed into the more conductive crystalline state). The tribological layer 50 is very thin, which reduces its horizontal conductivity.

The electrode 30 preferably has a conductivity that is neither too low nor too high, for example a conductivity intermediate between that of the material of the islands 75 in the crystalline state and that of this material in the amorphous state. The order of magnitude is 1 ohm-cm and carbon, optionally doped with adjuvants that increase or reduce its conductivity, is suitable for producing the electrode.

Reading is carried out by application of a lower voltage (1 to 2 volts) between the microtip and the electrode 30. The current that flows is measured and the amorphous or crystalline nature of the island placed under a microtip is deduced therefrom. The current remains very much confined in an island underneath the microtip, notably when the island has again become amorphous, due to the absence of electrical conductivity of the wells which surround the island.

With a memory structured in this way, it is possible to choose that the material in the non-recorded state be either amorphous or crystalline, whereas in memories having a continuous layer it is essential that the non-recorded state be the state in which the phase-change material is as insulated as possible (in practice, the amorphous state).

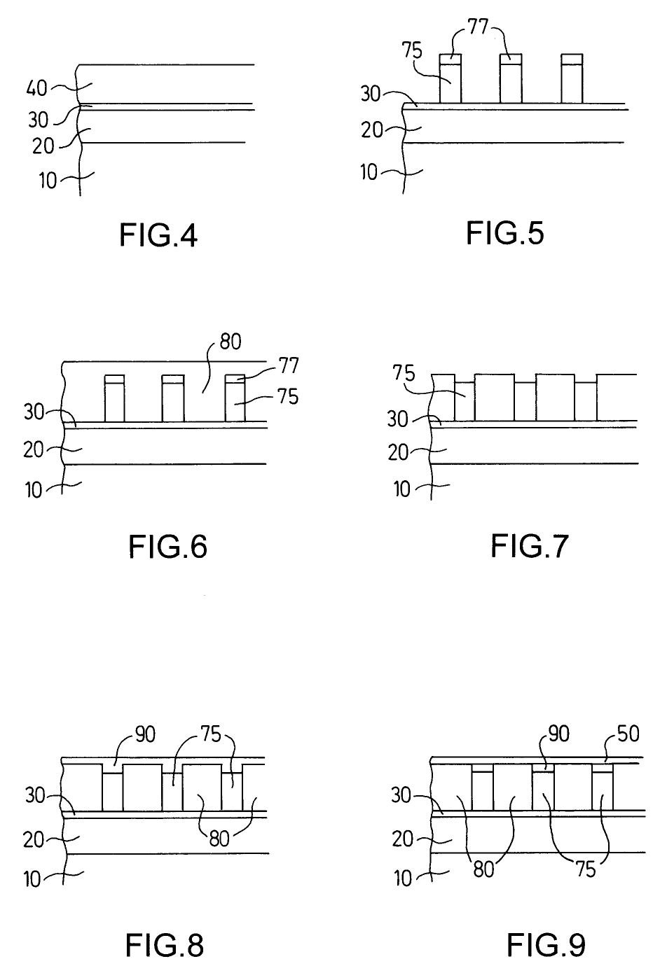

FIGS. 4 to 9 represent, by way of example, the steps of manufacturing such a memory in a first embodiment. In this embodiment, the embedded electrode is continuous as in FIG. 3 and the phase-change material is deposited onto the electrode.

One starts (FIG. 4) with a substrate 10 (silicon or glass or plastic) onto which a layer 20 that forms a thermal barrier (preferably 10 to 100 nanometers of silica or of silicon nitride or of a compound ZnS/SiO₂ known for its low thermal conduction) is deposited uniformly by plasma vapor deposition. Deposited next is a layer 30 constituting the common continuous electrode, for example a layer of less than 5 nanometers of titanium nitride or of carbon, the resistivity of which may be adjusted by the incorporation of metal elements (Ag, Cr, Ni, Au, for example). The proportion of carbon atoms having hybridization of sp³ and sp² orbital bonds may also be adjusted starting from the deposition pressure and temperature conditions to better control the resistivity.

Deposited on the electrode is a layer 40 of controllable phase-change material, preferably a chalcogenide such as Ge₂Sb₂Te₅ (the exact proportions of the constituents may vary, for example this may be Ge_{22.2}Sb_{22.2}Te_{55.6}) or AgInSbTe. The thickness of this layer may be around a hundred nanometers. The material is generally deposited in amorphous form.

Via photolithography (simplest solution) or via other processes (such as particle self-organization processes which will be mentioned later on and which allow a higher resolution, or else stamping processes using a mold etched with the desired pattern), a mask is formed for structuring the layer 40 with a view to delimiting individual islands 75 of layer of phase-change material that constitute the individual points of the memory. The mask may be a resist mask or a mineral mask obtained by transfer of the image from a resist mask. Once the mask 77 is formed, the layer 40 is attacked, for example by reactive ion beam etching, in the areas where it is not masked, in order to form the islands 75. FIG. 5 represents the islands covered by the masking layer 77 which was used to protect them during this structuring phase. The masking layer may be removed at this stage or may be kept, depending on its nature. In this example it is considered that it remains.

Deposited next (FIG. 6), onto the substrate thus covered with islands 75, is a layer of material which is electrically insulating and preferably a poor heat conductor. This material fills the spaces between the individual islands 75 by forming a network of wells 80 in which each well surrounds a respective island. The material may be a compound of silicon oxide and of zinc sulfide. Its thickness is greater than the height of the islands 75.

The excess height of layer 80 (and the mask 77 if it has not been removed before) is then removed (FIG. 7) by any known process (plasma, or chemical-mechanical polishing CMP).

Next, a layer 90 of encapsulating material that protects the phase-change layer is deposited (FIG. 8). This material may be titanium nitride or carbon rendered conductive by the presence of metallic impurities. The thickness of the layer 90 may be around 5 to 20 nanometers.

Finally, the substrate is planarized, for example by chemical-mechanical polishing, and a thin layer known as a “tribological layer” 50 is deposited that facilitates the sliding of the microtip and that protects it from excessive wear. This layer may be of the same nature as the layer 90, notably made of carbon; it is very thin (less than 10 nanometers), it must be sufficiently conductive vertically to allow the flow of a current through the phase-change layer, but it must be scarcely conductive horizontally so that there is no diversion of current toward another island 75 when the microtip is applied on top of an island. The material of the encapsulating layer 90 and the material of the tribological layer may also be deposited in a single step.

Another embodiment of the invention will now be described, in which the wells that surround the islands of phase-change material are constituted by the superposition of a first insulating (electrically and thermally) layer, an electrode and a second insulating layer. The phase-change layer is not deposited on top of the electrode but it passes through holes in the electrode. These holes physically correspond to the position of the islands.

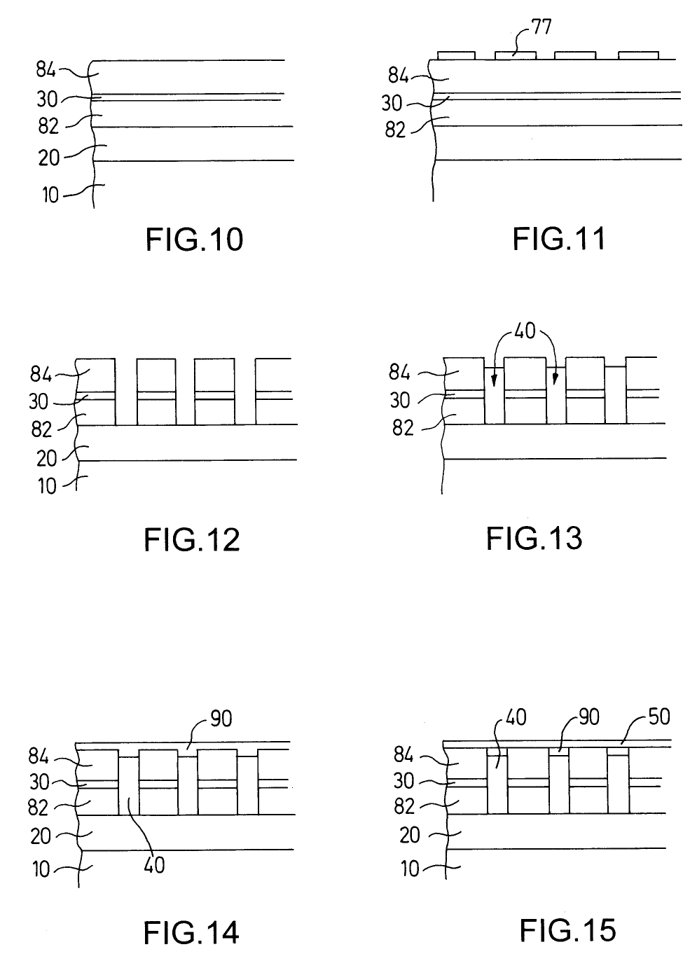

One starts (FIG. 10) with a substrate 10 (silicon or glass or plastic) onto which a layer 20 that forms a thermal barrier (preferably 10 to 100 nanometers of silica or of silicon nitride or of a compound ZnS/SiO₂ known for its low thermal conduction) is deposited uniformly by plasma vapor deposition. A first layer 82 of a thermally and electrically insulating material that will constitute, in part, the material of the wells surrounding the islands of phase-change material, is deposited. Deposited next is a layer 30 constituting the common continuous electrode, for example a layer of less than 10 nanometers of titanium nitride or of carbon, the resistivity of which may be adjusted by the incorporation of metal elements (Ag, Cr, Ni, Au, for example). The proportion of carbon atoms having hybridization of sp³ and sp² orbital bonds may also be adjusted starting from the deposition pressure and temperature conditions to adjust the resistivity. And a second layer 84, analogous to the layer 82, is deposited. The wells will be constituted by the superposition of the layers 82, 30 and 84.

Next, the steps for defining the well patterns are carried out. The simplest is to use a photolithography operation by depositing and etching a mask 77 for which the pattern is that of the wells to be produced (FIG. 11). It should be noted that the mask is complementary to that which is used in the previous example (FIG. 5).

The etch mask may be made from an irradiated photoresist or a layer of a material deformed by any molding or stamping process. It may also be produced from self-organization processes that will be mentioned later on.

The mask thus obtained makes it possible to transfer the masking pattern to the subjacent layers 84, 30, 82. This is done by ion beam etching or reactive ion beam etching. Therefore holes are formed in this stack of layers and only the pattern of wells remains; the etching is stopped when it reaches the bottom of the layer 20; the mask 77 is then removed by chemical or mechanical action (FIG. 12).

Next, a layer 40 of controllable phase-change material is deposited which at least partially fills the apertures formed in the wells. This material forms islands that are separated from one another and these islands constitute the individual memory zones (FIG. 13). The phase-change material is preferably sprayed over the entire surface and it is preferable to heat the substrate so that the material migrates to the bottom of the cavities. It is also possible to facilitate the migration of the phase-change material to the bottom of the cavities by increasing the wettability of the surface and this is possible by first spraying a very thin layer of carbon or of a material having wettability properties onto the surface comprising the cavities (for example: chromium, nickel).

If there is an excess of phase-change material, it is removed by etching so that this material does not completely fill the holes formed in the wells.

Deposited next, in a manner similar to that which was explained with reference to FIG. 8, is an encapsulating material 90, for example titanium nitride or carbon (FIG. 14).

The surface of the substrate is planarized by a chemical-mechanical polishing process and the process is completed by depositing a thin tribological layer 50 (FIG. 15) in the same manner as that which was explained with reference to FIG. 9: the layer may be made of carbon sprayed with metallic adjuvants that make it possible to adjust its resistivity.

The encapsulating material and the tribological layer may optionally be the subject of a single deposition step.

In the two preceding exemplary embodiments, the material of the individual islands (first material) is very different from the material of the wells (second material) since these are respectively a chalcogenide and a ZnS/SiO₂ compound. In a third exemplary embodiment, it is possible to use materials for the islands and the wells that are very similar to one another but differentiated from the point of view of the crystallization properties. Then use is made of a structured memory in which there is a layer of material which, for the main part, is a material capable of changing phase in a controlled manner during a thermal process, and the composition of the material is different in the islands and the wells which surround them so that the phase change is easier in the islands than in the wells. In other words, the memory zones are constituted overall by the same material as the wells which surround them, but the compositions are slightly different in the islands and the wells. In order to obtain this structure, the composition of a uniform layer deposited on the substrate is modified locally; this modification is carried out either in the islands or, on the other hand, in the wells which surround them. The modification in composition may be carried out by implantation, diffusion, doping with species which are chemically or structurally aligned with the controllable phase-change material. The method relies either on a mask for delimiting the implantation, doping or diffusion zones, or on a self-organization of the material to be diffused before carrying out a step of actual migration of the dopant in the controllable phase-change layer.

In one example, a base multilayer is produced as described previously (FIG. 4) with a uniform deposition of a layer of phase-change material (chalcogenide, GeSbTe or InSbTe); then an open mask is produced according to the pattern of the wells to be produced, by photolithography or stamping or self-organization; then gaseous species such as oxygen or nitrogen are diffused through the apertures of the mask, these gaseous species will reduce the conductivity of the phase-change material and therefore will make the phase change, by application of write current in the diffused zones, that is to say in the wells, very difficult. This diffusion process is controlled by the pressure and temperature conditions and the time the species to be diffused are present for. Finally, after having removed the mask, the tribological layer already mentioned is deposited. The presence of the tribological layer helps to stop the diffusion of oxygen or nitrogen into the material. Besides oxygen and nitrogen, it is possible to use hydrogen, or else a heavy dopant such as hafnium or gallium or argon. These heavy atoms tend to increase the crystallization temperature of the phase-change material, therefore tend to make the phase change more difficult.

The structure then comprises individual islands of the controllable phase-change material, surrounded by wells for which the conductivity has become much lower than that of the material of the islands (in their amorphous or crystalline state) so that the write microtip cannot pass a current into the wells which would risk changing the structure or the electrical conductivity thereof.

In another example, use is made, as a base material, of a compound of indium In, of antimony Sb and of tellurium Te (optionally containing gallium which tends to increase the crystallization temperature), and added locally to the islands but not to the wells are impurities of a chemical species (notably silver) which tends to facilitate the control of the crystallization (for example, because the incorporation of this species reduces the crystallization temperature). For example, a mask is formed on a layer of InSbTe or InSbTeGa material, the masking pattern being open at the locations corresponding to the individual islands to be formed; silver impurities are deposited onto this mask and diffuse into the InSbTe layer at the location where the mask is open. Here too, the mask may be formed from photolithography steps or by using a self-organization process.

In this approach, it is even possible to deposit the silver under conditions where it self-organizes itself into individual islands. Specifically, silver lends itself to a self-organization by prewetting, that is to say without there being a need for prior photolithography steps in order to define the islands. For example, with a phase-change material which is a germanium-antimony-tellurium alloy, rich in antimony and tellurium, and even optionally doped with gallium to increase the crystallization temperature and therefore make the phase change more difficult, it is possible to carry out the following production steps: the base multilayer is established as described previously (FIG. 4), with a substrate, a thermal barrier layer, an electrode, and a layer of phase-change material; it is possible to add a layer of carbon of very small thickness (less than 2 nanometers) to facilitate dewetting of the silver layer. A continuous, extremely thin layer of silver is deposited, having a thickness of the order of a few nanometers; by thermally-assisted self-organization (at a temperature of around 400° C.), the silver agglomerates into individual islands separated from one another following a relatively even pattern. By increasing the temperature the silver migrates into the phase-change material at the location where it has agglomerated, and it modifies the latter by lowering the crystallization temperature at these locations which become the individual islands of the memory.

Another approach, equivalent to the approach consisting in creating the islands by diffusion of silver, consists in doing the opposite: the mask is open at the location of the wells and not of the islands, one starts with a layer of easily crystallizable material (for example an AgInSbTe compound) and deposited on the mask, in view of a diffusion of species at the location where the mask is open, is an impurity such as hafnium (more generally atoms having a high atomic number) which tends to hinder any crystallization process. The material of the starting layer remains a controllable phase-change material outside of the wells defined by the mask, and it becomes a material with no possibility of phase control in the masked islands.

Thus, more generally, in these modes where the islands and the wells are essentially made from a common base material, one starts with a homogeneous layer of an active material and:
individual islands are rendered more active in terms of ease of phase change than the wells which surround them; or
on the other hand, wells are rendered less active in terms of ease of phase change than the individual islands surrounded by these wells.

The invention has mainly been described with regard to phase-change materials capable of moving from an amorphous state to a crystalline state in a reversible manner. It can also be applied, more generally, to other materials which, without strictly speaking having an amorphous phase and a crystalline phase, may have two states for which the electrical conductivities, or even other properties, may be detected by a microtip in read phase, the material possibly moving from one state to the other under the effect of an action of the microtip in the write phase.

In the foregoing, steps of defining patterns of islands or of wells which would be obtained by self-organization rather than by conventional photo-lithography steps have been alluded to several times. An important aspect of the present invention is the fact that it is proposed to define the individual zones of a memory that can be written and read with the aid of a microtip by using a step of self-organization of a thin layer of individual islands, in order to obtain patterns of higher resolution than that which can be obtained by photolithography. In practice, the self-organization step will be a step for constituting a mask from which it will be possible to carry out a selective operation in the unmasked zones of at least one layer of material located under the mask. The mask produced by self-organization could be a positive mask protecting zones that correspond to individual islands defining the individual points of the memory, or on the other hand a temporary negative mask that defines these islands but that is used to define a complementary positive mask that protects the wells that surround the individual islands. In the latter case, the mask defined by self-organization will be removed before carrying out steps for treating a layer located under the complementary positive mask.

In one example, a self-organized mask is constituted in the following manner: deposited on the surface to be masked is a layer of a few tens of nanometers constituted by a mixture of two different polymers which are respectively polystyrene and polymethyl methacrylate, in a solvent such as toluene which allows sufficient mobility of the polymers. The two polymers spontaneously organize themselves by separating from one another in a uniform manner: the polymethyl methacrylate forms hexagonal cylindrical blocks embedded in a uniform polystyrene matrix. The diameter of the blocks and the periodicity of the network depend, notably, on the molecular weights of the compounds. A heat treatment of long duration (several tens of hours at a temperature of around 150° C.) stabilizes this organization.

In order to obtain this self-organization, it is desirable to pretreat the surface (silicon or silicon oxide or nitride, for example) onto which the polymers are deposited, for example by rubbing it with a random blend of the polymers; the surface thus treated may be the surface of the layer for encapsulation of the memory layer (made of carbon, silicon, oxide, etc.). This prevents one of the two polymers from wetting the surface more than the other and then prohibits the formation of cylindrical blocks.

After polymerization, it is possible to selectively remove one of the polymers with a chemical that dissolves it without attacking the other polymer. For example, exposure to ultraviolet radiation degrades the polymethyl methacrylate while at the same time increasing the polymerization of the polystyrene, and it only remains to remove the polymethyl methacrylate residues with acetic acid aided by ultrasonic stirring.

A mask is thus obtained from which the pattern is a network of polystyrene wells having regular holes. This mask may be used, for example, to define, by etching or diffusion of the patterns into the subjacent layer, these patterns corresponding to the holes and therefore to individual islands. For example, if the mask is deposited onto a layer of silicon oxide, it is possible to make holes in the oxide layer that correspond with the holes of the mask by attack using CHF₃ by reactive ion beam etching in the presence of argon; CHF₃ does not attack the polystyrene but attacks the oxide. The silicon oxide layer thus etched with the self-organized pattern may itself act as a mask.

If need be, the mask thus produced may be used to define a complementary mask via a lift-off operation, that is to say an operation in which a material is deposited both on the mask and in the holes of the mask and then both the mask and the product that covers it are removed while allowing the product to remain where it had been deposited in the holes of the mask.

The article by Guarini et al., “Nanoscale patterning using self-assembled polymers for semiconductor applications” published in the Journal of Vacuum Science Technology B19(6) November/December 2001, and also the article by Guarini et al., “Process integration of self-assembled polymer templates into silicon nano-fabrication” in the same journal B20(6), November/December 2002, explain the principles of this self-organization.

It should be noted that in order to facilitate a uniform self-organization, it is preferable to divide the overall surface of the zone onto which the copolymers are deposited into small surface elements separated from one another (for example, it is possible to define rows and columns free of polymers, in order to delimit a network of small rectangles (for example having side of a few hundred nanometers) inside which the organization will be more uniform than if the entire surface was self-organized from one block).

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. A data storage memory, that can be written and read by using at least one write or read microtip which comes near to a point zone to be written or to be read on the surface of a substrate, either in order to change the physical state of this zone, when writing or erasing, or in order to determine the physical state of the zone, when reading, the data stored in the zone being defined by the physical state of the zone, wherein the surface of the substrate is subdivided into a set of individual islands of a layer of a first sensitive material capable of changing state under the action of the write microtip, each island being surrounded by a well formed by a second material which is not significantly sensitive to the action of the write microtip, this second material completely separating the individual islands from one another, and wherein the material of the wells is mainly formed by the same material as the material of the islands, differentiation impurities being contained in one or the other of the two materials, these impurities being chosen so that they facilitate the chance of state for the first material and/or so that they make the chance of state more difficult for the second material.

2. The memory as claimed in claim 1, wherein the first sensitive material is composed of a material having a controllable phase change, notably a compound based on tellurium Te or on antimony Sb or on germanium Ge, such as GeTe or SbTe or a chalcogenide, and notably a GeSbTe or AgInSbTe compound, capable of reversibly changing from an amorphous state to a crystalline state.

3. The memory as claimed in claim 1, wherein the material of the wells that surround the islands of the sensitive layer is an electrically insulating material.

4. The memory as claimed in claim 3, wherein the material of the wells has a low thermal conductivity.

5. The memory as claimed in claim 1, wherein the substrate is covered with a layer forming a thermal barrier made from a material that is a poor heat conductor, and with a continuous electrode which covers the barrier layer, the continuous electrode being covered with islands of the layer of sensitive material surrounded by wells formed by the second material.

6. The memory as claimed in claim 1, wherein the substrate is covered with a layer forming a thermal barrier made from a material that is a poor heat conductor, covered with islands of the material of the sensitive layer, and the islands are surrounded by wells formed by the superposition of the second layer, with an electrode and with a third electrically-insulating and thermally-insulating layer, the electrical connection between an island and the electrode taking place through the slice of the electrode around the periphery of the island.

7. The memory as claimed in claim 5, wherein the set of islands and wells is covered with a layer for reducing friction of the microtip, preferably made of carbon.

8. The memory as claimed in claim 6, wherein the substrate is made of silicon, glass, or organic material.

9. The memory as claimed in claim 5, wherein the layer that forms a barrier is made of silica, silicon nitride, or preferably from a zinc sulfide ZnS and a silica SiO₂ compound.

10. The memory as claimed in claim 1, wherein said impurities are chosen so that they reduce electrical conduction of the material.

11. The memory as claimed in claim 10, wherein the differentiation impurities are contained in the material of the islands and comprise silver.

12. The memory as claimed claim 10, wherein the impurities are contained in the material of the wells and comprise hafnium, oxygen, nitrogen, hydrogen, gallium or argon.

13. A process for manufacturing a memory that can be written and read by using at least one write or read microtip which comes near to an elementary zone to be written or to be read on the surface of a substrate, wherein the elementary zones are individual islands of a first material, surrounded by insulating wells composed mainly of the same material as the islands, the material of the wells being doped differently from the material of the islands, and wherein the islands are defined by using a step of self-organization of at least one substance which, during its deposition onto a surface of a substrate, is capable of self-organizing itself into a pattern of individual islands separated from one another.

14. The process as claimed in claim 13, wherein the substance that self-organizes itself is an impurity intended to be diffused into a subjacent layer in order to define the individual islands.

15. The process as claimed in claim 13, wherein the substance that self-organizes itself is a substance that acts as a mask for the treatment of a subjacent layer.

16. The process as claimed in claim 15, wherein the substance that self-organizes itself is a polymer, and this polymer is deposited at the same time as a second polymer that has affinities with the first, the bonding forces between the two polymers creating a self-organization in which the first polymer agglomerates into individual islands surrounded by a matrix of the second polymer.
